(19) United States
(12) Patent Application Publication
(10) Pub. No.: US 2019/0296692 A1
(43) Pub. Date: Sep. 26, 2019

(54) CURRENT MODE/VOLTAGE MODE SWITCHABLE AMPLIFIER

(71) Applicant: QUALCOMM Incorporated, San Diego, CA (US)

(72) Inventors: Chirag Dipak PATEL, San Diego, CA (US); Lai Kan LEUNG, San Marcos, CA (US); Xinmin YU, San Diego, CA (US); Timothy Donald GATHMAN, San Diego, CA (US)

(21) Appl. No.: 16/054,921

(22) Filed: Aug. 3, 2018

Related U.S. Application Data
(60) Provisional application No. 62/646,818, filed on Mar. 22, 2018.

(51) Int. Cl. H03F 1/02; H03F 1/32; H03F 3/45; G05F 1/56; G05F 3/26

(52) U.S. Cl. CPC H03F 1/0211; H03F 1/3211; G05F 3/262; G05F 1/56; H03F 3/45179

(57) ABSTRACT

A switchable amplifier exhibits multiple modes of operation including a current mode and a voltage mode. The switchable amplifier includes a first transistor having a gate terminal coupled to a drain terminal, one or more second transistors having a gate terminal coupled to the gate terminal of the first transistor, a third transistor and a bias resistor across the third transistor. The third transistor is coupled between the gate terminal of the first transistor and the gate terminal of the one or more second transistors.

### CROSS-REFERENCE TO RELATED APPLICATION

The present application claims the benefit of U.S. Provisional Patent Application No. 62/646,818, filed on Mar. 22, 2018, and titled “CURRENT MODE/VOLTAGE MODE SWITCHABLE AMPLIFIER,” the disclosure of which is expressly incorporated by reference herein in its entirety.

### TECHNICAL FIELD

The present disclosure generally relates to amplifiers. More specifically, aspects of the present disclosure relate to current mode/voltage mode switchable amplifiers.

### BACKGROUND

Amplifiers are commonly used in various electronic devices or communications systems to provide signal amplification. Different types of amplifiers are available for different uses. For example, a wireless communications device (e.g., a cellular phone) may include a transmitter and a receiver for bi-directional communication. The receiver may use a low noise amplifier (LNA), while the transmitter may use a power amplifier (PA). In addition, the receiver and the transmitter may use variable gain amplifiers (VGAs).

Some of the communications systems (e.g., fifth generation (5G)) impose strict linearity specifications on a receive signal path as well as high gain. This is true even when the received signal is a wanted or desired signal that is free of jammers. Linearity is the behavior of a circuit, particularly an amplifier, in which the output signal strength varies in direct proportion to the input signal strength. For example, even without jammers, the linearity specification is very high for 5G systems. Thus, non-linearity affecting the desired signal can limit throughput in some cases (e.g., where the throughput should be at a highest level).

### SUMMARY

In an aspect of the present disclosure, a switchable amplifier includes a first transistor having a gate terminal coupled to a drain terminal. The switchable amplifier also includes one or more second transistors having a gate terminal coupled to the gate terminal of the first transistor. The switchable amplifier further includes a third transistor and a bias resistor across the third transistor. The third transistor is coupled between the gate terminal of the first transistor and the gate terminal of the one or more second transistors.

In another aspect of the present disclosure, a switchable amplifier includes a first transistor. The switchable amplifier also includes one or more second transistors having a gate coupled to a gate of the first transistor. The switchable amplifier further includes means for switching the switchable amplifier between a first mode and a second mode. The switching means is coupled between the gate of the first transistor and the gate of the one or more second transistors.

In yet another aspect of the present disclosure, a method switches between multiple modes in an amplifier. The method includes enabling a switch between a gate of a diode-connected transistor and a gate of one or more second transistors to short a bias resistor coupled between the gate of the diode-connected transistor and the gate of the one or more second transistors. Enabling the switch causes the amplifier to operate in a first mode based on a first mode-switching indicator. The method further includes disabling the switch to un-short the bias resistor to operate the amplifier in a second mode based on a second mode-switching indicator.

In another aspect of the present disclosure, a switchable amplifier includes a current mirror circuit having a first transistor and a second transistor. The second transistor is configured to receive a radio frequency (RF) input signal. The switchable amplifier further also includes a third transistor configured to adjust an input impedance of the second transistor.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless system.

FIG. 2 shows a block diagram of a wireless communications device.

FIG. 3 illustrates a switchable amplifier, according to aspects of the present disclosure.

FIG. 4 illustrates a switchable amplifier in the current mode of operation, according to aspects of the present disclosure.

FIG. 5A illustrates a switchable amplifier in the voltage mode of operation, according to aspects of the present disclosure.

FIG. 5B illustrates a resistor configuration that achieves an intermediate mode of operation, according to one or more aspects of the present disclosure.

FIG. 6 illustrates a programmable bias structure including a programmable bias/current source configured to provide bias/current to a switchable amplifier, according to aspects of the present disclosure.

FIGS. 7A, 7B, and 7C illustrate switchable amplifiers with different geometrically adjustable gain, according to aspects of the present disclosure.

FIG. 7D illustrates a switchable amplifier having multiple outputs, according to aspects of the present disclosure.

FIG. 8 illustrates a switchable amplifier having a radio frequency domain coupled to a direct current (DC) domain according to aspects of the present disclosure.

FIG. 9 illustrates a phased array according to one or more aspects of the present disclosure.

FIG. 10 depicts a simplified flowchart of a method of switching between multiple modes in an amplifier according to aspects of the present disclosure.

FIG. 11 is a block diagram showing an exemplary wireless communications system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR” and the use of the term “or” is intended to represent an “exclusive OR”.

Some communications systems (e.g., fifth generation (5G)) impose strict linearity specifications on a receive signal path as well as high gain. This is true even when the received signal is a desired signal that is free of jammers. For example, even without jammers, the linearity specification is very high for 5G systems compared to legacy systems (e.g., 3G/4G) due to the much wider signal bandwidths utilized in the 5G system. Thus, non-linearity affecting the desired signal can limit throughput in some cases (e.g., where the throughput should be at a highest level). The high linearity specification even without jammers is very different from fourth generation (4G) systems where the jammers impose some of the strictest linearity specifications. While these system specifications are favorable to high linearity, there are use cases where the high linearity is not specified (e.g., a low power mode). However, increased gain may still be specified. An example of such a use case includes a quadrature phase shift keying (QPSK) mode or during wake-up mode of a receiver when a very low signal is being received. In these cases, reducing power consumption becomes a major concern.

Existing solutions do not have a good way to trade off current consumption for linearity, while maintaining gain and noise figure. For example, in some applications, the high linearity specification is in tradeoff with the high gain specification. It is therefore desirable to achieve high gain without specifying high linearity in order to save power or reduce power consumption.

Some existing implementations include a tunable feedback loop across an amplifier (e.g., a variable gain amplifier (VGA)) that relaxes linearity, increases the gain, and provides a current adjustment feature. However, at some high frequencies (e.g., millimeter wave (mmW) bands and some intermediate frequencies (IFs) ˜6-10 GHz), this solution is subject to reduced reverse isolation. Further, some feedback is specified for the highest gain mode to turn down the current when desirable. Thus, in normal operation when the high linearity is specified, the communications system is not operating optimally because it cannot support the low power mode (e.g., high gain), without trading off a main mode of operation (e.g., high linearity).

Another existing implementation includes a main amplifier path and an auxiliary amplifier path where the auxiliary amplifier path is activated in the low power mode. However, this implementation is subject to deficiencies, especially at high frequencies (e.g., millimeter wave (mmW) bands) because of unwanted parasitics impacting nominal performance and power consumption. Moreover, the auxiliary amplifier path consumes area as well as complexity of routing to and around the auxiliary amplifier path. Additionally, the implementation is also subject to the tradeoff between low power mode and nominal operation. Thus, it is desirable to offer a design that switches between a high linearity mode and a low power mode without an operational tradeoff in the high linearity mode.

Aspects of the present disclosure are directed to a switchable amplifier (e.g., a switchable variable gain amplifier (VGA)) that exhibits multiple modes of operation including a current mode and a voltage mode. For example, the amplifier can switch between a current mode of operation that is characterized by high linearity and a voltage mode of operation where the current can be tuned down to achieve a low power mode. The current mode is used during nominal operation or a main mode of operation. For example, the current mode may be used for lower bit rate modulation (e.g., quadrature phase shift keying (QPSK) or higher bit rate modulation quadrature amplitude modulation (QAM)). According to aspects of the present disclosure, a same or similar gain can be maintained for the different modulation schemes to improve power consumption while sacrificing some linearity. Current mode denotes an impedance relationship between a driving and a second amplifier (e.g., the VGA or a driving amplifier to drive other stages in voltage or current mode) where the output impedance of the driving amplifier is significantly greater (e.g., by more than five times (5×) or less in some cases) than the input impedance of the second amplifier. In some cases, however, the output impedance of the driving amplifier is less than five times the input impedance of the second amplifier. The current mode achieves better intrinsic linearity and droop performance over a wide range of gain.

The voltage mode may be used for higher gain operation where linearity can trade off with power. For example, the voltage mode is optimized for high gain and low power. Voltage-mode denotes an impedance relationship between a driving amplifier and the second amplifier where the input impedance of the second amplifier is greater than the driving amplifier. The same devices that are used for the current mode are used for the voltage mode, and the same gain modes can be achieved in either mode of operation.

In one aspect of the present disclosure, an amplifier (e.g., the VGA) is configured to switchably operate in a first mode (e.g., the current mode) and a second mode (e.g., the voltage mode). The amplifier includes a first transistor, one or more second transistors (or a set of second transistors), a third transistor, and a bias resistor. The one or more second transistors is in a current mirror configuration with the first transistor. In some aspects, the one or more second transistors may form a cascode device. For example, the cascode device may be constructed from two transistors (field effect transistors (FETs)), with one operating as a common source and the other as a common gate. The cascode device improves input-output isolation as there is no direct coupling from the output to the input. This eliminates the Miller effect and thus contributes to a much higher bandwidth.

The third transistor is coupled between a gate of the first transistor and a gate of the second transistor(s). For example, each transistor of the second set of transistors may have a gate that is coupled (e.g., selectively coupled) to the third transistor. The third transistor is configured to switch the amplifier from the first mode to the second mode of operation. The bias resistor is coupled across the source and the drain terminals of the third transistor. For example, the third transistor is configured to adjust an input impedance seen at an input of the second transistor(s) in order to switch the amplifier from the first mode to the second mode by selectively shorting the bias resistor.

The amplifier further includes a reference current source. The reference current source may be coupled to the first transistor. In one aspect of the present disclosure, the reference current source may be a programmable current source coupled to the first transistor. In some aspects, a drain of the first transistor is coupled to a gate of the first transistor to generate a bias voltage at the gate of the first transistor. The amplifier may also include an inductor coupled to the second transistor(s). The inductor (e.g., choke) is configured to resonate out a parasitic path associated with the second transistor(s). The inductor may also be configured to resonate out a parasitic path associated with a capacitor coupled to the second transistor(s) and to resonate out a parasitic path associated with additional transistor stages coupled to the second transistor(s).

The third transistor is sized to minimize its resistance when activated versus the impedance of the first transistor. The geometric size of the third transistor is greater than or equal to a geometric size of the second transistor(s). A geometric size of the first transistor is greater than or equal to a sixteenth of a geometric size of the second transistor(s) to avoid excessive power consumption. For example, when the second transistor(s) include multiple transistors an aggregate geometric size of the transistors is compared to the geometric size of the third transistor.

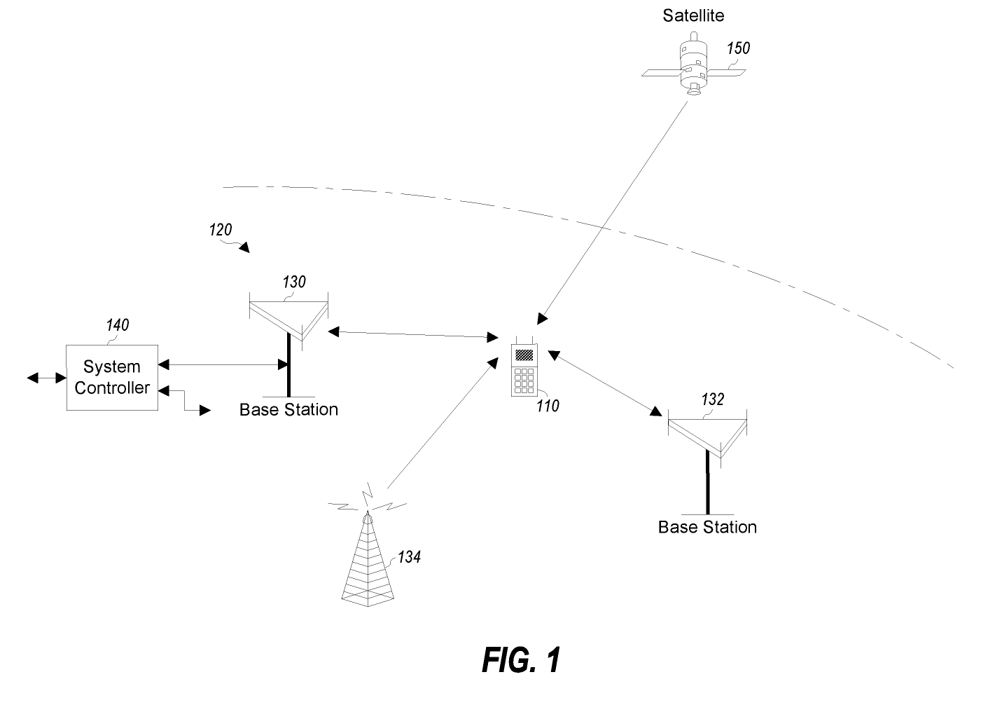

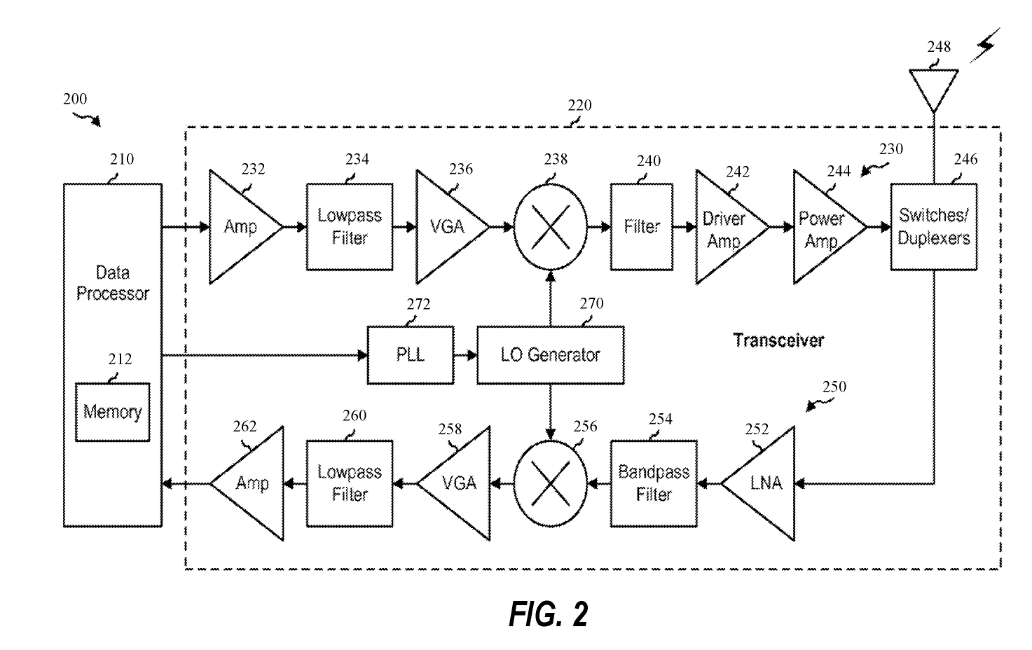

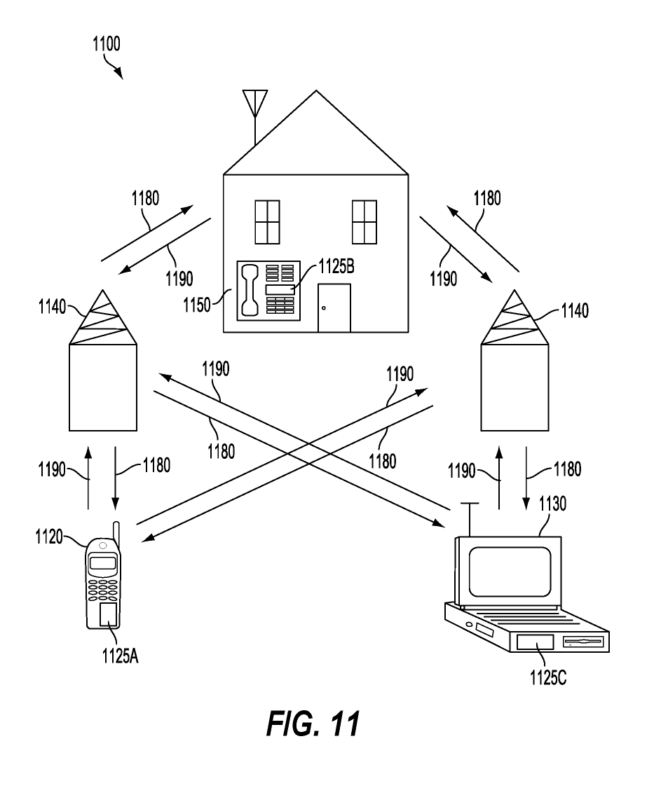

The aspects of the present disclosure may be implemented in the systems of FIGS. 1 and 11 as well as the device of FIG. 2.

FIG. 1 shows a wireless device 110 communicating with a wireless communications system 120 including the switchable amplifier described herein. The wireless communications system 120 may be a 5G system, a long term evolution (LTE) system, a code division multiple access (CDMA) system, a global system for mobile communications (GSM) system, a wireless local area network (WLAN) system, millimeter wave (mmW) technology, or some other wireless system. A CDMA system may implement wideband CDMA (WCDMA), time division synchronous CDMA (TD-SCDMA), CDMA2000, or some other version of CDMA. In a millimeter wave (mmW) system, multiple antennas are used for beamforming (e.g., in the range of 30 GHz, 60 GHz, etc.) For simplicity, FIG. 1 shows the wireless communications system 120 including two base stations 130 and 132 and one system controller 140. In general, a wireless system may include any number of base stations and any number of network entities.

A wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may include the switchable amplifier and may be capable of communicating with the wireless communications system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communications such as LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690, ultra-high band from 3400 to 3800 MHz, and long-term evolution (LTE) in LTE unlicensed bands (LTE-U/LAA) from 5150 MHz to 5950 MHz. Low-band, mid-band, high-band, ultra-high band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to 5 carriers in one or two bands in LTE Release 11.

FIG. 2 shows a block diagram of an exemplary design of a wireless communications device or wireless communications device 200 that may include a switchable amplifier. In this exemplary design, the wireless communications device 200 includes a data processor 210 and a transceiver 220. The transceiver 220 includes a transmitter 230 and a receiver 250 that support bi-directional wireless communications. In general, the wireless communications device 200 may include any number of transmitters and any number of receivers for any number of communications systems and any number of frequency bands.

In the transmit path, the data processor 210 processes data to be transmitted and provides an analog output signal to the transmitter 230. Within the transmitter 230, the analog output signal is amplified by an amplifier (Amp) 232, filtered by a low pass filter 234 to remove images caused by digital-to-analog conversion, amplified by a VGA 236 (e.g., a switchable amplifier described herein), and upconverted from baseband to radio frequency (RF) by a mixer 238. The upconverted signal is filtered by a filter 240, further amplified by a driver amplifier 242 and a power amplifier 244, routed through switches/duplexers 246, and transmitted via an antenna 248.

In the receive path, the antenna 248 receives signals from base stations and/or other transmitter stations and provides a received signal, which is routed through the switches/duplexers 246 and provided to the receiver 250. Within the receiver 250, the received signal is amplified by a low noise amplifier (LNA) 252, filtered by a bandpass filter 254, and downconverted from RF to baseband by a mixer 256. The downconverted signal is amplified by a VGA 258, filtered by a low pass filter 260, and amplified by an amplifier 262 to obtain an analog input signal, which is provided to the data processor 210.

FIG. 2 shows the transmitter 230 and the receiver 250 implementing a direct-conversion architecture, which frequency converts a signal between RF and baseband in one stage. The transmitter 230 and/or the receiver 250 may also implement a super-heterodyne architecture, which frequency converts a signal between RF and baseband in multiple stages. A local oscillator (LO) generator 270 generates and provides transmit and receive LO signals to the mixers 238 and 256, respectively. A phase locked loop (PLL) 272 receives control information from the data processor 210 and provides control signals to the LO generator 270 to generate the transmit and receive LO signals at the proper frequencies.

FIG. 2 shows an exemplary transceiver design. In general, the conditioning of the signals in the transmitter 230 and the receiver 250 may be performed by one or more stages of amplifier, filter, mixer, etc. These circuits may be arranged differently from the configuration shown in FIG. 2. Furthermore, other circuits not shown in FIG. 2 may also be used in the transmitter and the receiver. For example, matching circuits may be used to match various active circuits in FIG. 2. Some circuits in FIG. 2 may also be omitted. The transceiver 220 may be implemented on one or more analog integrated circuits (ICs), radio frequency ICs (RFICs), mixed-signal ICs, etc. For example, the amplifier 232 through the power amplifier 244 in the transmitter 230 may be implemented on an RFIC. The driver amplifier 242 and the power amplifier 244 may also be implemented on another IC external to the RFIC.

The data processor 210 may perform various functions for the wireless communications device 200, e.g., processing for transmitted and received data. A memory 212 may store program codes and data for the data processor 210. The data processor 210 may be implemented on one or more application specific integrated circuits (ASICs) and/or other ICs.

As shown in FIG. 2, a transmitter and a receiver may include various amplifiers. Each amplifier at RF may have input impedance matching and output impedance matching, which are not shown in FIG. 2 for simplicity.

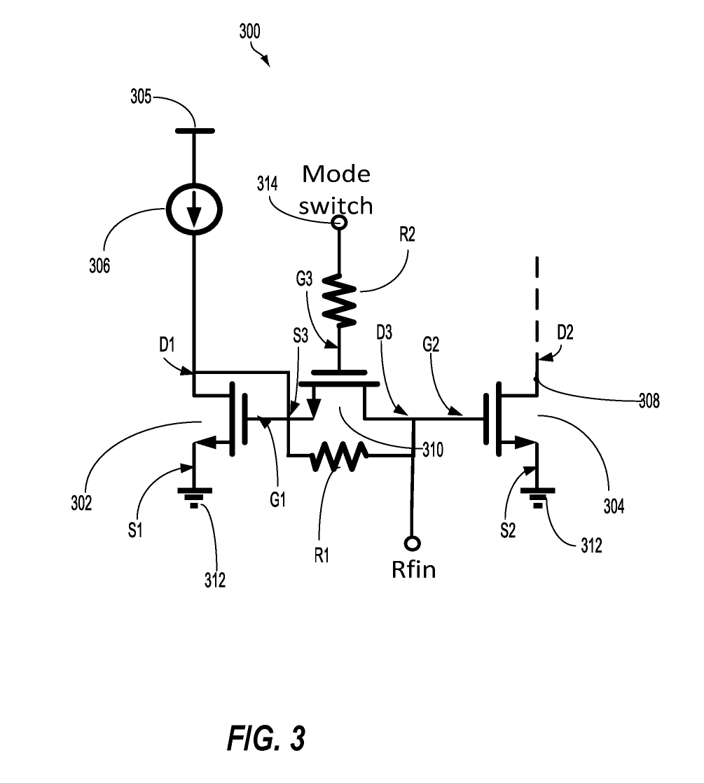

FIG. 3 illustrates a switchable amplifier 300, according to aspects of the present disclosure. The switchable amplifier 300 includes a first transistor 302 comprising a diode-connected transistor and a second transistor 304 (or a second set of transistors) in a current mirror configuration with the first transistor 302. The second transistor 304 may be referred to as a transconductance device. A reference current source 306 is coupled to the first transistor 302. For example, the reference current source 306 is coupled to a drain D1 of the first transistor 302 to provide a reference current to the first transistor 302. The current source 306 receives power supply from a power supply source 305. The drain D1 of the first transistor is coupled to a gate G1 of the first transistor 302 to provide a bias voltage at the gate G1 of the first transistor 302. A source S1 of the first transistor 302 may be coupled to a ground 312.

The second transistor 304 or the second set of transistors is/are arranged in the current mirror configuration with the first transistor 302 such that an output current through the second transistor 304 or current through the one or more of the second set of transistors is equal to or is a multiple of the reference current. For example, the output current flows through a node 308 (corresponding to an output of the switchable amplifier 300) at a drain D2 of the second transistor 304 or a drain of one or more of the second set of transistors. A source S2 of the second transistor 304 is coupled to the ground 312.

A third transistor 310 is coupled between the gate G1 of the first transistor 302 and a gate G2 of the second transistor 304 (or a gate of the one or more of the second set of transistors). The third transistor 310 is configured to switch the amplifier 300 from a first mode (e.g., the current mode) to a second mode (e.g., the voltage mode). For example, the third transistor 310 is configured to adjust an input impedance of the second transistor 304 to switch the amplifier 300 from the current mode to the voltage mode. A bias resistor R1 is coupled across the third transistor 310 to facilitate switching between the different modes. For example, the bias resistor R1 is coupled between a drain D3 of the third transistor 310 and a source S3 of the third transistor 310. A gate G3 of the third transistor 310 is coupled to a transistor control source or mode switch source 314 that generates a control signal for the third transistor 310. In some aspects, the gate G3 is coupled to the transistor control source 314 via a resistor R2. The current mode is associated with a low input impedance while the voltage mode is associated with a high input impedance. A radio frequency input signal to the amplifier 300 may be received at a node Rfin.

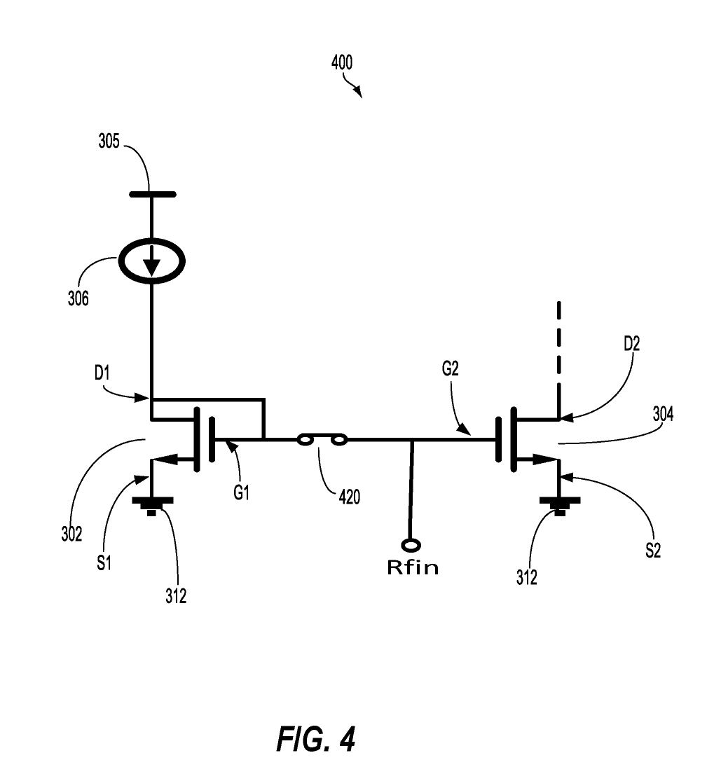

FIG. 4 illustrates a switchable amplifier 400 in the current mode of operation, according to aspects of the present disclosure. For illustrative purposes, some of the labelling and numbering of the devices and features of FIG. 4 are similar to those of FIG. 3. However, FIG. 4 shows the third transistor 310 (shown in FIG. 3) forming a short circuit 420 based on the control signal provided to the gate G3 (shown in FIG. 3) of the third transistor 310. For example, a control device (not shown) determines when to operate in the current mode, voltage mode, or an intermediate mode (discussed further below) and generates the control signal based on the determination. In this case, the bias resistor R1, is electrically removed from the circuit due to the short circuit.

As seen in FIG. 4, in the current mode, the third transistor 310 or mode switch acts as the short circuit 420 between the first transistor 302 and the second transistor 304. For example, the third transistor 310 is turned on in the current mode to create the short circuit 420 between the gate G1 of the first transistor 302 and the gate G2 of the second transistor 304. In the current mode, the control signal from the transistor control source 314 (or mode switch source) is enough to turn on the third transistor 310 to create the short circuit 420 between the first transistor 302 and the second transistor 304. The resistance looking into the gate G1 of the first transistor 302 is 1/gm (where gm=transconductance), which is a small impedance compared to a conventional gate, source, or drain impedance of a transistor. Thus, the input impedance (which corresponds to 1/gm) of the switchable amplifier 400 (e.g., VGA) is small compared to conventional amplifier output impedances.

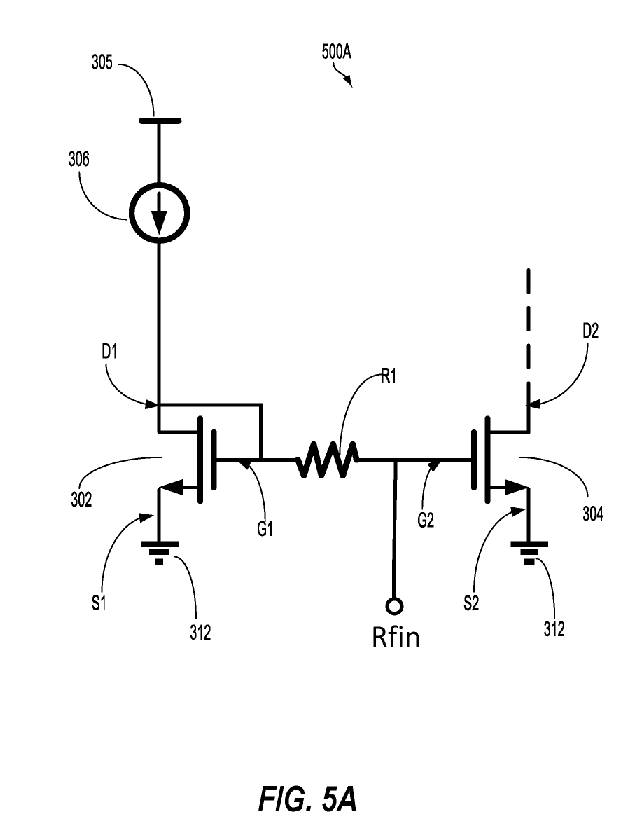

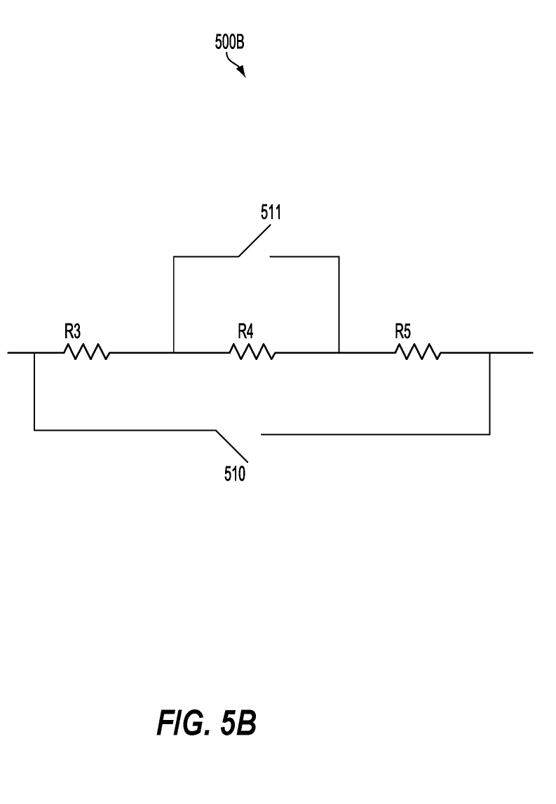

FIG. 5A illustrates a switchable amplifier 500A in a voltage mode of operation, according to aspects of the present disclosure. For illustrative purposes, some of the labelling and numbering of the devices and features of FIG. 5A are similar to those of FIG. 3. However, FIG. 5A shows the third transistor 310 (shown in FIG. 3) forming a substantially open circuit based on the control signal provided to the gate G3 (shown in FIG. 3) of the third transistor 310. The substantially open circuit causes a signal between the first transistor 302 and the second transistor 304 to traverse a high resistance (e.g., through bias resistor R1) in the voltage mode.

For example, to switch into the voltage mode, the mode switch or the third transistor 310 is turned off to create a path through resistor R1. In the voltage mode, the gain is dependent on current through the second transistor 304 rather than a geometric size ratio of the transistors (as is the case with the current mode). Thus, the current can be adjusted or tuned (e.g., turned down) to balance out the gain. In current mode, the gain of the switchable amplifier (e.g., the switchable amplifier 300 of FIG. 3) is dependent on the geometric size ratio of the transistors. One way to adjust the geometric size ratio is by changing a number of transistors of a second transistor or set of transistors. For example, the adjustment may correspond to an adjustment of the size of the second transistor 304 of FIG. 3 or an adjustment of the number of transistors of a second set of transistors turned on at any time.

The transistors of the switchable amplifier (e.g., the switchable amplifier 300, 400 and 500A) may include N-type (or NMOS) transistors,. However, P-type (or PMOS) transistors can also be used to implement the switchable amplifier. For example, to achieve the PMOS transistor implementation, the Vdd/ground are swapped and the NMOS and PMOS transistors are swapped.

In some aspects, a resistance value of the resistor R1 may be selected or adjusted to achieve some intermediate mode (e.g., a gain stepping mode) between the current mode and the voltage mode, as illustrated in FIG. 5B.

FIG. 5B illustrates a resistor configuration 500B that achieves an intermediate mode of operation, according to one or more aspects of the present disclosure. For illustrative purposes, some of the labelling and numbering of the devices and features of FIG. 5B are similar to those of FIGS. 3, 4, and 5A. The resistor configuration 500B may include resistors R3, R4, and R5 and switches 510 and 511. The resistor configuration 500B may replace the resistor R1 of FIGS. 3 and 5A as well as the switch (e.g., the third transistor 310). For example, the resistor R1 may be replaced with the three resistors R3, R4, and R5. The third transistor 310 may be replaced with the switch 510 and an additional switch 511 is included to bypass one or more of the resistors R3, R4, and R5 to adjust the impedance of the resistor configuration 500B. For example, the switch 511 is across the additional resistor R4 to selectively bypass the resistor R4. The switch 510 is across all three resistors R3, R4 and R5 and is turned off to bypass all three resistors R3, R4 and R5 in the current mode of operation. The radio frequency signal in this implementation is not affected by the additional switch 511 because the additional switch 511 is blocked by the resistors R3 and R5.

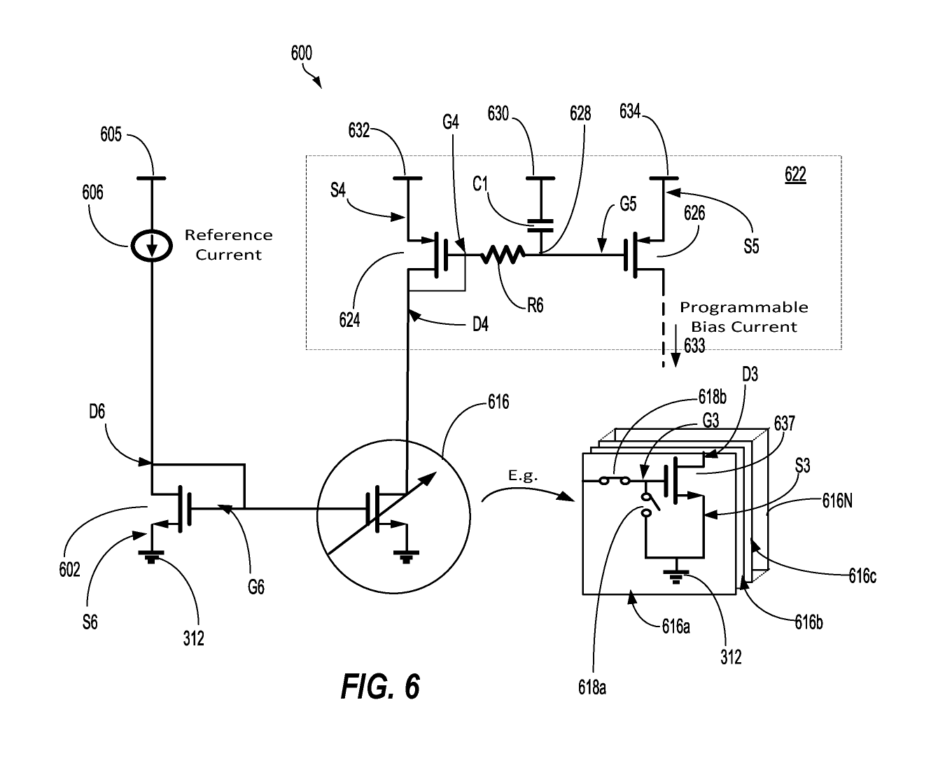

In one aspect of the present disclosure, a programmable current source may adjust the bias current of a switchable amplifier (e.g., the amplifier 500A), as illustrated in FIG. 6.

FIG. 6 illustrates a programmable bias structure 600 including a programmable bias/current source 622 configured to provide bias/current to a switchable amplifier (e.g., the switchable amplifier 300), according to aspects of the present disclosure. For example, the current source 306 of FIG. 3 can be replaced with the programmable bias/current structure 600 to provide bias/current to the switchable amplifier 300 via the first transistor 302. In one aspect, the bias/current 633 is provided to the drain D1 of the first transistor 302, shown in FIG. 3.

A bias/current adjustment circuit 616 may be a second set of transistors 616 that may include multiple selectable transistors or adjustable transistors. For example, a desirable number of transistors of the multiple selectable transistors 616 can be turned on at any given time to adjust the programmable bias current 633 going through a diode-connected transistor (e.g., the first transistor 302 of FIG. 3).

In one aspect of the disclosure, the selectable transistors 616 are transconductance devices. Thus, the selectable transistors 616 form a set of transconductance slices with each transconductance slice being selectable based on a switch (e.g., switch 618) controlled by a control device (not shown). The transconductance slices may include up to N transconductance slices (where N is an integer). For example, the transconductance slices include a first transconductance slice 616a, a second transconductance slice 616b, and a third transconductance slice 616c up to an Nth transconductance slice 616N. Each of the transconductance slices 616a, 616b, 616c, and up to 616N includes a transistor (e.g., a transistor 637), a switch (e.g., switch 618) coupled between a gate (e.g., the gate G2) of the transistor 637 and the ground 312.

For example, the switch 618a is open and the switch 618b is closed when the transistor 637 is on and the switch 618a is closed and the switch 618b is open to disable or unselect the transistor 304. In the disabled mode, the input to the gate G3 is driven to ground (e.g., the ground 312) via the switch 618a, thereby bypassing the transistor 637. A source (e.g., a source S3) of each of the selectable transistors 616 is coupled to ground (e.g., the ground 312). A drain (e.g., a drain D3) of each of the selectable transistors 616 is coupled to the programmable bias/current source 622.

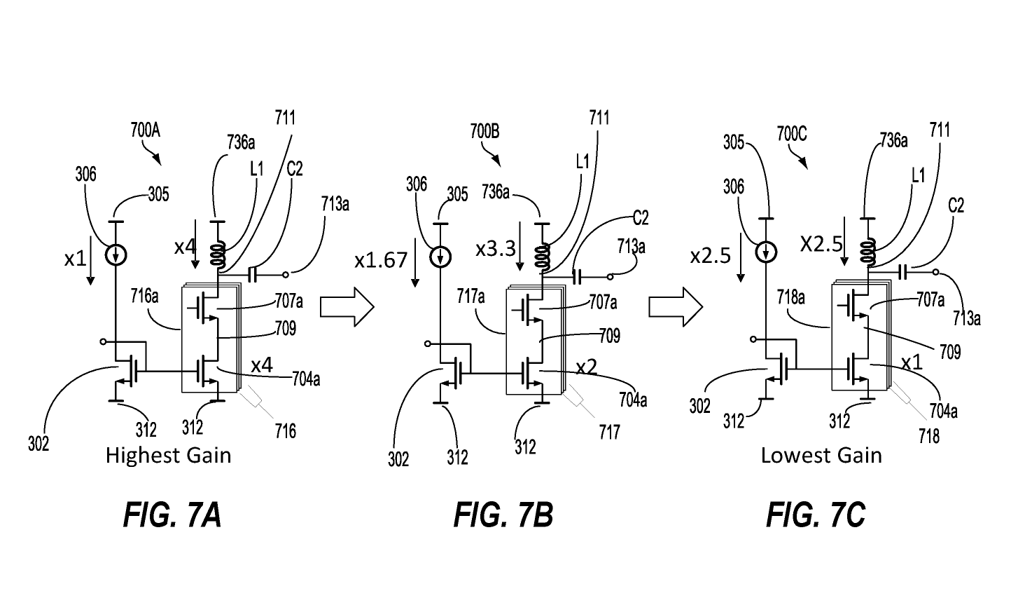

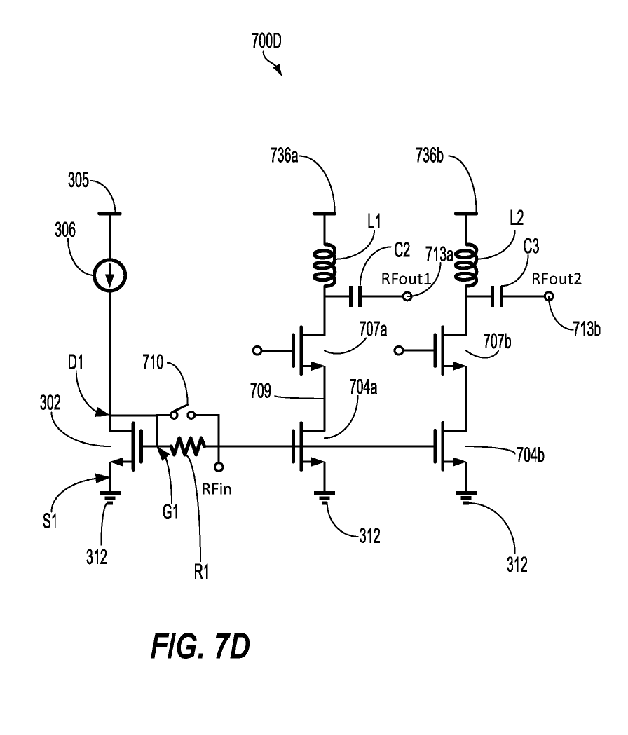

In one aspect of the disclosure, the multiple selectable transistors 616 may be coupled to the programmable bias/current source 622. Current through a drain D4 of a transistor 624 of the programmable bias/current source 622 is controlled by a reference current source 606 and the bias/current adjustment circuit 616. The programmable bias/current source 622 may receive power from various power supplies 630, 632, and 634. The power supplies 630, 632, and 634 may be the same but different from the power supply 305 of FIG. 3 or the power supply 736a of FIGS. 7A, 7B and 7C. For example, the power supply 632 may be coupled to a fourth transistor 624 to provide power to the fourth transistor 624 via a source S4 of the fourth transistor 624. The power supply 634 may be coupled to a fifth transistor 626 to provide power to the fifth transistor 626 via a source S5 of the fifth transistor 626.

The transistors of the programmable bias/current source 622 may include N-type transistors, P-type transistors, or a combination of both. For example, the fourth transistor 624 and the fifth transistor 626 may be P-type transistors. Alternatively, the fourth transistor 624 and the fifth transistor 626 may be N-type transistors. The fourth transistor 624 may be in in a current mirror configuration with respect to a fifth transistor 626. The programmable bias/current source 622 may also include a resistor R6 between a gate G4 of the fourth transistor 624 and a gate G5 of the fifth transistor 626. Further, the programmable bias/current source 622 includes a capacitor C1 between a node 628 and the power supply 630. The node 628 is coupled between the resistor R6 and the gate G5 of the fifth transistor 626. A drain D4 of the fourth transistor 624 may be coupled to one or more drains (e.g., the drain D3) of the selectable transistors 616.

Current associated with the programmable bias/current source 622 is based on a reference current from a reference current source 606 coupled between a power supply 605 and a diode-connected transistor that includes a transistor 602 having its drain D6 coupled to its gate G6 and its source S6 coupled to a ground (e.g., the ground 312). The gate G6 may be coupled to the gate G3 via the switch 618b. The reference current 606 may be nominally fixed for all gain modes although it can still change as a result of temperature or process variations.

FIGS. 7A, 7B, and 7C respectively illustrate switchable amplifiers 700A, 700B, and 700C with different geometrically adjustable gains, according to aspects of the present disclosure. For example, each of FIGS. 7A, 7B, and 7C represent different gain modes achieved by adjusting a geometric size ratio of the first transistor 302 of the switchable amplifier (e.g., 700A, 700B, and 700C) to a second set of transistors (e.g., transconductance slices 716, 717, or 718) arranged in a current mirror configuration with the first transistor 302. For ease of explanation, the device for achieving the switching between the different modes (e.g., the third transistor 310 and the resistor R1) are omitted in FIGS. 7A, 7B, and 7C.

For illustrative purposes, some of the labelling and numbering of the devices and features of FIGS. 7A, 7B, and 7C are similar to those of FIGS. 3, 4, 5A, and 5B. For example, each of the switchable amplifiers 700A, 700B, and 700C includes the first transistor 302, the ground 312, and the power supply source 305. However, the switchable amplifiers 700A, 700B, and 700C further include a second set of transistors represented by transconductance slices (e.g., a first set of transconductance slices 716, a second set of transconductance slices 717, and a third set of transconductance slices 718) with different geometric ratios relative to the first transistor 302. Each of the switchable amplifiers 700A, 700B, and 700C has outputs at their respective drains coupled to an inductor L1 that receives power supply from a power supply source 736a and a second capacitor C2.

The capacitor C2 blocks DC levels at an output node 713a. For example, the output may be taken at node 713a where the capacitor C2 serves as a DC blocker to the output node 713a. The inductor L1 is configured to resonate out a parasitic path associated with the second set of transistors represented by the transconductance slices 716, 717, and 718. The inductor L1 may also be configured to resonate out a parasitic path associated with the capacitor C2 coupled to the second set of transistors and to resonate out a parasitic path associated with any additional transistor stages coupled to the second set of transistors.

The inductor L1 may also allow bias voltage to the one or more second transistors in a way that is free of the bias voltage supply impedance. In this case, the inductor L1 acts as a radio frequency current source such that the one or more second transistors see a high impedance looking into the inductor L1. Thus, all of the output from the one or more second transistors goes to a node 711, through the capacitor C2 to the node 713a.

A first transconductance slice 716a, 717a, and/or 718a of the set of transconductance slices (e.g., the first, second, and/or the third set of transconductance slices 716, 717, and 718) includes a first transconductance transistor 704a coupled to a first cascode transistor 707a in a cascode configuration. For example, a source of the first cascode transistor 707a may be coupled to a drain of the first transconductance transistor 704a at a node 709. In some aspects, current flows through the node 711 coupled to a drain of the first cascode transistor 707a. A gate of the first cascode transistor 707a may be used to turn off or turn on one or more of the transconductance slices to control the geometric ratio. For example, when the transconductance slice is turned on, a voltage is set to optimize or improve a current mirror ratio/performance to keep a voltage on a drain of the transconductance (gm) device the same as a voltage at a gate of the transconductance device.

The current mode of operation is based on the geometric size ratio of the first transistor to the second set of transistors (e.g., the transconductance slices 716, 717, or 718) of the switchable radio frequency (RF) amplifier (e.g., the switchable amplifiers 700A, 700B, and 700C). In this mode, the diode-connected transistor (the first transistor 302) linearizes the switchable amplifier (e.g., 700A, 700B, or 700C) through analog “pre-distortion.” The gain of the switchable amplifier becomes ratio-metric rather than being dependent on power consumption or the size of the transconductance device. For example, the gain of the amplifier is defined by the geometric size ratio of the first transistor 302 to the second set of transistors (e.g., the transconductance slices 716, 717, or 718). A number of transconductance slices may be increased to increase the gain. Some of the transconductance slices can be disabled to reduce the gain in accordance with a gain stepping implementation.

Each of the first set of transconductance slices 716, the second set of transconductance slices 717, and the third set of transconductance slices 718 includes a desirable or selected set of transconductance transistors (e.g., the first transconductance transistor 704a) and set of cascode transistors (e.g., first cascode transistor 707a). The sets of transconductance slices can be more or less than three. One or more sets of transconductance slices (e.g., 716, 718, and/or 718) may be selected to achieve a desirable gain of the switchable amplifier (e.g., the switchable amplifier 700A, the switchable amplifier 700B, or the switchable amplifier 700C). For example, the gain of the switchable amplifiers 700A, 700B, and 700C is stepped up/down or adjusted by tuning a number of transconductance (gm) slices used.

Referring to FIG. 7A, a number of transconductance slices in the first set of transconductance slices 716 is adjusted (e.g., increased) to increase the gain of the switchable amplifier 700A by a multiple of four (×4). For example, a geometric size ratio of the first set of transconductance slices 716 to the first transistor 302 is four. In this case, the current flowing through the node 711 coupled to a drain of the first cascode transistor 707a is four times the current through the drain of the first transistor 302. Some of the transconductance slices can be disabled to reduce the gain in accordance with a gain stepping implementation, as illustrated in FIG. 7B.

Referring to FIG. 7B, a number of transconductance slices in the second set of transconductance slices 717 is adjusted to reduce the gain (relative to the gain of FIG. 7A) of the switchable amplifier 700B by a multiple of two (×2 or 6 dB)). For example, a geometric size ratio of the second set of transconductance slices 717 to the first transistor 302 is 2. However, an output intercept point (OIP3) is maintained by increasing current density at lower gain modes. An overall current consumption is similar for all of the gain modes illustrated in FIGS. 7A, 7B, and 7C. For example, an overall current consumption in FIG. 7A may correspond to a sum of the current in both the first transistor and the second set of transistors (e.g., a sum of ×1 and ×4; for a total of 5 units (×5)). In FIG. 7B, the reference current can be increased by a multiple of 1.67 while the output current is reduced to a multiple of 3.3 (total 1.67+3.3˜5 units) to balance a same overall current while tolerating a higher jammer power and maintaining the output power of the switchable amplifier 700B. However, current consumption in the voltage mode is smaller than current consumption in the current mode. For example, in the voltage mode, there is a tradeoff between power consumption and power handling capability/linearity for a same gain.

Referring to FIG. 7C, a number of transconductance slices in the third set of transconductance slices 718 is adjusted (e.g., reduced) to reduce the gain (relative to the gain of FIG. 7A) of the switchable amplifier 700C by a multiple of 1 (×1)). For example, a geometric size ratio of the third set of transconductance slices 718 to the first transistor 302 is 1. In FIG. 7C, the reference current can be increased by a multiple of 2.5 while the output current is reduced to a multiple of 2.5 (total 2.5+2.5=5 units) to balance a same overall current while tolerating a higher jammer power and maintaining the output power of the switchable amplifier 700C.

The drawback, however, is that this implementation specifies an increased amount of current at the diode-connected transistor (e.g., the first transistor 302), which is undesirable for a low power mode, such as the wake-up mode of the receiver when a very low signal is being received and high linearity is not specified. To mitigate this issue, the current mode operation can be switched to voltage mode by adding a switch (e.g., the third transistor 310) with a large bias resistor (e.g., the bias resistor R1) across the switch in between the gates of the transconductance (gm) slices and the diode-connected transistor (e.g., the first transistor 302). The switching of the modes is sporadic and may be determined by the control device based on an application or a mode of operation of a user equipment or transmit/receive chain. These operations may include the wake-up mode of the receiver when a very low signal is being received.

FIG. 7D illustrates a switchable amplifier 700D having multiple outputs, according to aspects of the present disclosure. The multiple outputs (e.g., multiple mirrored outputs) can be used for carrier aggregation. In carrier aggregation, a receiver receives multiple separate signals, which are separated in the transceiver to be separately demodulated by a modem. Thus, with multiple outputs, the signals can be separately sent to separate downconverters.

For illustrative purposes, some of the labelling and numbering of the devices and features of FIG. 7D are similar to those of FIGS. 3, 4, 5A, 7A, 7B and 7C. For example, FIG. 7D illustrates two transconductance slices having separate outputs taken at nodes 713a and 713b. The first transconductance slice may be the first transconductance slice 716a, 717a, or 718a of the set of transconductance slices (e.g., the first, second, and/or the third set of transconductance slices 716, 717, and 718).

The first transconductance slice includes the first transconductance transistor 704a coupled to the first cascode transistor 707a in a cascode configuration. The second transconductance slice includes a second transconductance transistor 704b coupled to a second cascode transistor 707b in the cascode configuration. For example, each of the first transconductance slice and the second transconductance slice has an output (e.g., output at the output nodes 713a and 713b) at their respective drains coupled to respective inductors L1 and L2 that receive power supply from their respective power supply sources 736a and 736b. The outputs from the first cascode transistor 707a and the second cascode transistor 707b, respectively, go to the output nodes 713a and 713b through the capacitors C2 and C3.

A switch 710 of FIG. 7D adjusts an impedance to switch the amplifier 700D from the current mode to the voltage mode. In some aspects, the switch 710 can also be a transistor (e.g., the third transistor 310).

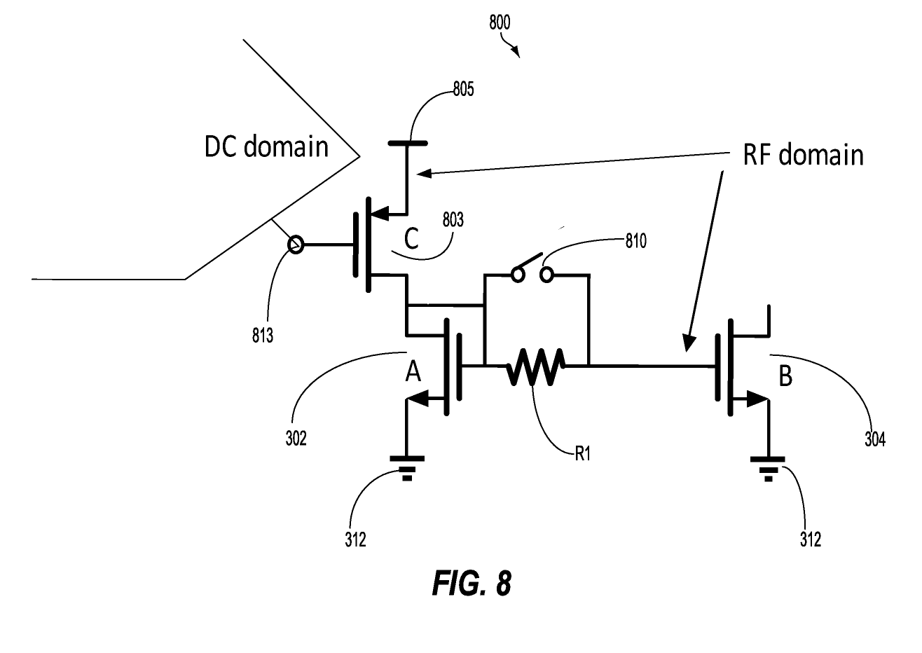

FIG. 8 illustrates a switchable amplifier 800 having a radio frequency domain coupled to a direct current (DC) domain, according to aspects of the present disclosure. For illustrative purposes, some of the labelling and numbering of the devices and features of FIG. 8 are similar to those of FIGS. 3, 4, and 5A. However, while the third transistor 310 of FIG. 3 switches the amplifier 300 to adjust the impedance and to switch from the current mode to the voltage mode, a switch 810 of FIG. 8 adjusts the impedance to switch the amplifier 800 from the current mode to the voltage mode. In some aspects, the switch 810 can also be a transistor (e.g., the third transistor 310). The current source in the radio frequency domain may include a transistor 803 that receives power from a power supply 805.

The transistor 803 may be configured to operate as a current source (e.g., the current source 306). In one aspect of the disclosure, the transistor 803 may be a P-type transistor with a source coupled to the power supply 805 and a drain coupled to the first transistor 302. In some aspects, the transistor 803 configured to operate as a current source may be replaced with a programmable bias current source (e.g., the programmable bias/current source 622). For example, the current source may be programmable based on the configuration similar to the configuration illustrated with respect to the programmable bias/current source 622 of FIG. 6.

The switchable amplifier 800 may be implemented in a radio frequency domain and coupled to one or more devices (not shown) in the DC domain. For example, the one or more devices in the DC domain may tune the current source (which includes the transistor 803) in the radio frequency domain. For example, a tuning signal from the DC domain may be received at a node 813 that is coupled to a gate of the transistor 803. The tuning signal may be generated based on a discrete/digital control implementation.

The radio frequency domain implementation may account for parasitics (e.g., parasitic resistances and capacitances). For example, the switch 810 may have an optimal size or impedance (e.g., ˜five (5) ohms) to minimize parasitic capacitance and the impedance can be as large as possible without disturbing radio frequency performance. Additionally, in the radio frequency domain implementation, the layout is such that the first transistor 302 and the second transistor 304 are very close together and placed in a matched configuration or in a configuration to reduce/minimize parasitics. In some aspects, the first transistor 302 and the second transistor 304 are integrated together. For example, a distance between the first transistor 302 and the second transistor 304 may be less than ten (10) to twenty (20) micrometers. The first transistor 302 and the second transistor 304 are both implemented in the radio frequency domain and have a same routing priority. Similarly, the first transistor 302 and the transistor 803 are very close together and placed in a matched configuration or in a configuration to reduce/minimize parasitics. For example, a distance between the first transistor 302 and the transistor 803 may be less than ten (10) to twenty (20) micrometers.

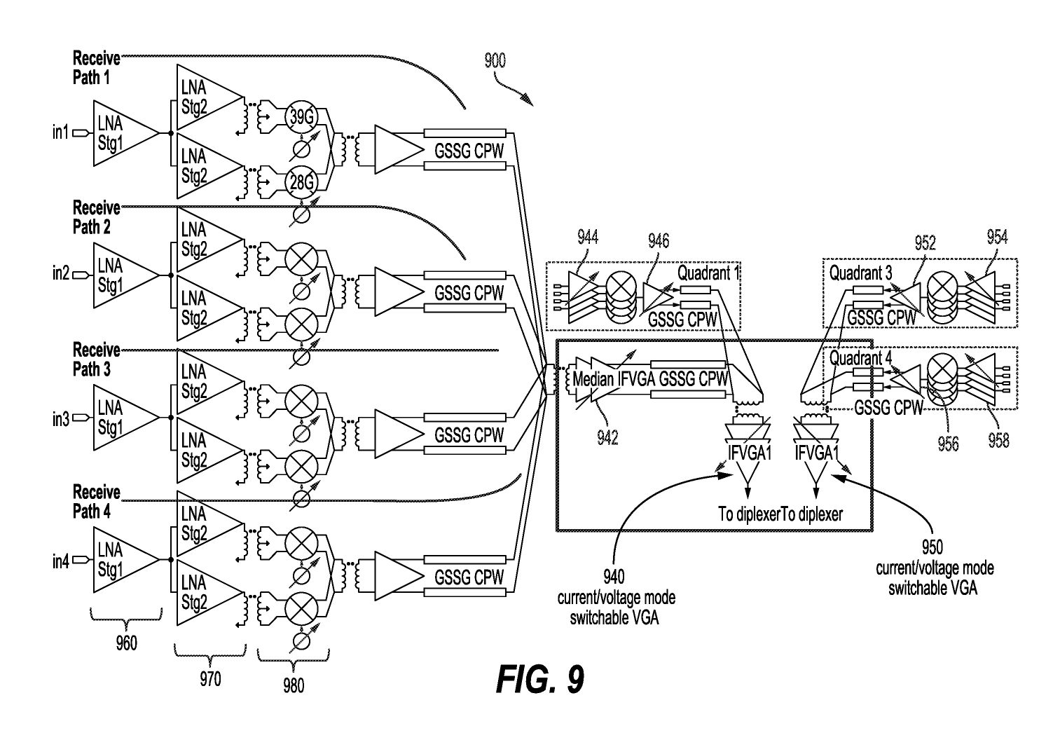

FIG. 9 illustrates a phased array 900, according to one or more aspects of the present disclosure. The phased array 900 includes multiple receive paths having inputs (e.g., in1, in2, in3, and in4) from multiple antennas (not shown) that lead into multiple low noise amplifiers (LNAs) (e.g., LNAs 960 and 970) and mixers (e.g., mixers 980) in the receive paths. The phased array 900 includes one or more median variable gain amplifiers (VGAs) that feed into one or more switchable amplifiers. For example, a first set of the switchable amplifiers includes a current/voltage mode switchable VGA 940 and a second set of the switchable amplifiers includes a current/voltage mode switchable VGA 950. The current/voltage mode switchable VGA 940 may be coupled to one or more median VGAs (or intermediate frequency VGAs). The one or more median VGAs may include sets of median VGAs 942, 944, 946, 952, 954, 956, and 958.

In one aspect of the present disclosure, the multiple receive paths include receive path 1, receive path 2, receive path 3, and receive path 4 that converge into the median VGA 942. Another set of four receive paths (not shown) may converge into the median VGAs 944 and 946. An additional set of four receivers may converge into the median VGAs 952 and 954. Yet another set of four receive paths (not shown) may converge into the median VGAs 956 and 958. Furthermore, the median VGAs 942, 944, and 946 converge to the current/voltage mode switchable VGA 940 while the median VGAs 952, 954, 956, and 958 converge to the current/voltage mode switchable VGA 950. The output of the current/voltage mode switchable VGA 940 and the current/voltage mode switchable VGA 950 go through a filter (e.g., a diplexer).

While the switchable amplifiers in this case are discussed in the context of a phased array, the switchable amplifiers can be used in other configurations. For example, the switchable amplifiers can be used between an LNA (e.g., the LNA 252 of FIG. 2) and a mixer (e.g., the mixer 256 of FIG. 2) in a receive path. The switchable amplifier is equally applicable in a transmit chain or transmitter (e.g., as a pre-amplifier).

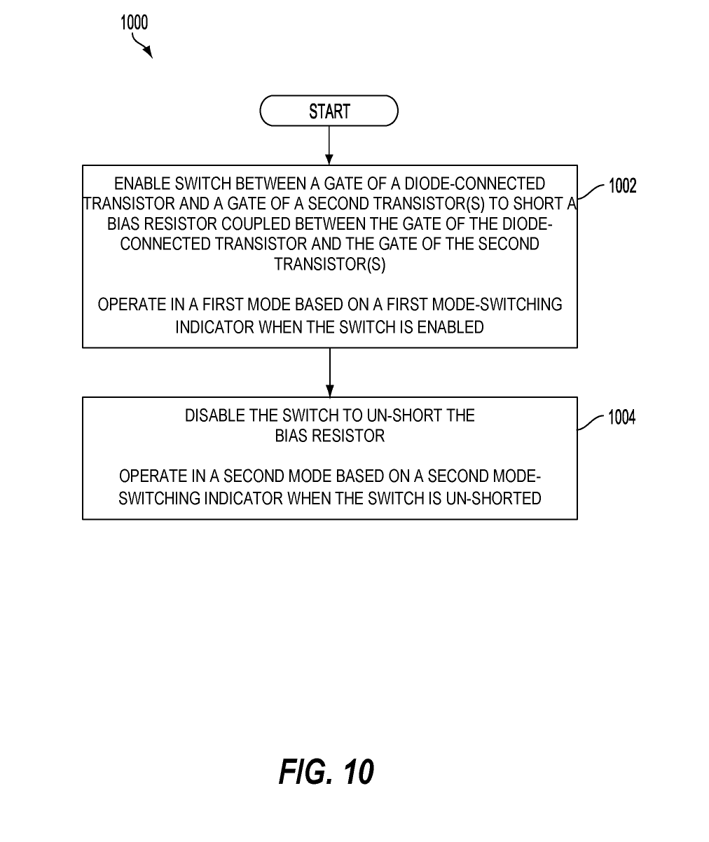

FIG. 10 depicts a simplified flowchart of a method 1000 of switching between multiple modes in an amplifier. At block 1002, a switch between a gate of a diode-connected transistor and a gate of one or more second transistors is enabled. Enabling the switch shorts a bias resistor coupled between the gate of the diode-connected transistor and the gate of the one or more second transistors. Accordingly, the amplifier operates in a first mode based on a first mode-switching indicator. At block 1004, the switch is disabled to un-short the bias resistor. Thus, the amplifier operates in a second mode based on a second mode-switching indicator.

According to one aspect of the present disclosure, an amplifier is described. The amplifier includes means for switching the amplifier from a first mode to a second mode. The mode switching means is coupled between a gate of the first transistor and a gate of the second transistor. The mode switching means may, for example, be the third transistor 310, the switch 510 and/or a switch 810. In another aspect, the aforementioned means may be any module or any apparatus or material configured to perform the functions recited by the aforementioned means.

FIG. 11 is a block diagram showing an exemplary wireless communications system 1100 in which a configuration of the disclosure may be advantageously employed. For purposes of illustration, FIG. 11 shows three remote units 1120, 1130, and 1150 and two base stations 1140. It will be recognized that wireless communications systems may have many more remote units and base stations. Remote units 1120, 1130, and 1150 include IC devices 1125A, 1125C, and 1125B that include the disclosed amplifier. It will be recognized that other devices may also include the disclosed amplifier, such as the base stations, switching devices, and network equipment. FIG. 11 shows forward link signals 1180 from the base station 1140 to the remote units 1120, 1130, and 1150 and reverse link signals 1190 from the remote units 1120, 1130, and 1150 to base station 1140.

In FIG. 11, remote unit 1120 is shown as a mobile telephone, remote unit 1130 is shown as a portable computer, and remote unit 1150 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 11 illustrates remote units according to the aspects of the disclosure, the disclosure is not limited to these exemplary illustrated units. Aspects of the disclosure may be suitably employed in many devices, which include the amplifier.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic device, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communications media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

What is claimed is:

1. A switchable amplifier, comprising:
a first transistor having a gate terminal coupled to a drain terminal;
at least one second transistor having a gate terminal coupled to the gate terminal of the first transistor;
a third transistor coupled between the gate terminal of the first transistor and the gate terminal of the at least one second transistor; and
a bias resistor across the third transistor.

2. The switchable amplifier of claim 1, further comprising a reference current source coupled to the first transistor or a programmable current source coupled to the first transistor.

3. The switchable amplifier of claim 1, wherein the third transistor is configured to switch the amplifier between a first mode and a second mode.

4. The switchable amplifier of claim 3, wherein the first mode comprises a current mode and the second mode comprises a voltage mode.

5. The switchable amplifier of claim 3, wherein the third transistor is configured to adjust an input impedance of the at least one second transistor to switch the amplifier between the first mode and the second mode.

6. The switchable amplifier of claim 1, further comprising:
an inductor coupled to the at least one second transistor;
a capacitor coupled to the at least one second transistor; and
additional transistor stages coupled to the at least one second transistor.

7. The switchable amplifier of claim 1, further comprising a cascode device having the at least one second transistor.

8. The switchable amplifier of claim 1, wherein a geometric size of the third transistor is greater than or equal to a geometric size of the at least one second transistor.

9. The switchable amplifier of claim 1, wherein a geometric size of the first transistor is greater than or equal to a sixteenth of an aggregate geometric size of the at least one second transistor.

10. The switchable amplifier of claim 1, wherein the at least one second transistor includes a plurality of second transistors, in which the plurality of second transistors are selectable to adjust gain that is based at least in part on a geometric size ratio of the plurality of second transistors to the first transistor.

11. The switchable amplifier of claim 1, further comprising a fourth transistor coupled to the first transistor and separated from the first transistor by less than twenty micrometers.

12. The switchable amplifier of claim 1, further comprising a programmable bias current coupled to the at least one second transistor.

13. The switchable amplifier of claim 1, further comprising multiple outputs.

14. A method of switching between multiple modes in an amplifier, the method comprising:
enabling a switch between a gate of a diode-connected transistor and a gate of at least one second transistor to short a bias resistor coupled between the gate of the diode-connected transistor and the gate of the at least one second transistor to operate the amplifier in a first mode based at least in part on a first mode-switching indicator: and
disabling the switch to un-short the bias resistor to operate the amplifier in a second mode based at least in part on a second mode-switching indicator.

15. The method of claim 14, further comprising adjusting a bias current to the amplifier during mode-switching triggered by the first mode-switching indicator or the second mode-switching indicator.

16. The method of claim 14, further comprising adjusting output signal properties including signal bandwidth and droop observed at either an intermediate frequency or at baseband during a mode-switching triggered by the first mode-switching indicator or the second mode-switching indicator.

17. A switchable amplifier, comprising:
a first transistor;
at least one second transistor having a gate coupled to a gate of the first transistor; and
means for switching the amplifier between a first mode and a second mode, the means for switching coupled between the gate of the first transistor and the gate of the at least one second transistor.

18. The switchable amplifier of claim 17, further comprising a reference current source coupled to the first transistor or a programmable current source coupled to the first transistor.

19. The switchable amplifier of claim 17, wherein a drain of the first transistor is coupled to the gate of the first transistor to generate a bias voltage at the gate of the first transistor.

20. The switchable amplifier of claim 17, wherein the first mode comprises a current mode and the second mode comprises a voltage mode.

21. The switchable amplifier of claim 17, wherein the mode switching means further comprises means for adjusting an input impedance of the at least one second transistor to switch the amplifier from the first mode to the second mode.

22. A switchable amplifier, comprising:
a current mirror circuit comprising a first transistor and a second transistor, the second transistor configured to receive a radio frequency (RF) input signal; and
a third transistor configured to adjust an input impedance of the second transistor.

23. The switchable amplifier of claim 22, wherein the switchable amplifier is configured to operate between at least a first mode and a second mode based at least in part on the adjusted input impedance.

24. The switchable amplifier of claim 23, wherein the first mode comprises a current mode and the second mode comprises a voltage mode.

25. The switchable amplifier of claim 22, wherein the third transistor is configured to adjust the input impedance via a selective shorting of a bias resistor coupled between a gate of the first transistor and a gate of the second transistor.

26. The switchable amplifier of claim 25, wherein the bias resistor is configured to operate the switchable amplifier in an intermediate mode via a selective adjustment of a resistance value of the bias resistor.
